(19) United States
(12) Patent Application Publication
(10) Pub. No.: US 2026/0113919 A1
(43) Pub. Date: Apr. 23, 2026

(54) SUBSTRATE PROCESSING DEVICE

(71) Applicant: TDK CORPORATION, Tokyo (JP)

(72) Inventors: Yohei TANAKA, Tokyo (JP); Osamu SHINDO, Tokyo (JP); Hiroshi KOIZUMI, Tokyo (JP); Masato SAWADA, Tokyo (JP); Makoto YAMASHITA, Tokyo (JP); Yasuo KATO, Tokyo (JP)

(73) Assignee: TDK CORPORATION, Tokyo (JP)

(21) Appl. No.: 19/115,416

(22) PCT Filed: Sep. 27, 2023
(86) PCT No.: PCT/JP2023/035294

§ 371 Date: Mar. 26, 2025

(30) Foreign Application Priority Data
Sep. 29, 2022 (JP) 2022-156621

(51) Int. Cl. H05K 13/04; H05K 13/00

(52) U.S. Cl. CPC H05K 13/04; H05K 13/0015

(57) ABSTRACT

A substrate processing device includes: a base part that receives a load; an upper jig plate that is provided with a heat source; a pressure application plate that is attached to the upper jig plate and that applies a pressure to a to-be-pressured object; and a support part that is interposed between the base part and the upper jig plate and that supports the upper jig plate for the base part. The support part includes support bodies formed from a ceramic-based material, and an air layer surrounding the support bodies.

### TECHNICAL FIELD

The present disclosure relates to a substrate processing device for processing a substrate on which a plurality of elements is disposed.

### BACKGROUND

As a device for forming an element array composed of a plurality of elements on a substrate, there is a substrate processing device. For example, a substrate processing device described in Patent Document 1 includes a pressure application means for applying pressure to a plurality of elements temporarily fixed to a substrate for final fixation and a heating means for heating the substrate or the like at the time of pressure application using the pressure application means.

In recent years, along with die shrink of elements, an element array composed of elements having a size (height) of several um may be formed on a substrate. To homogenously provide the substrate with such fine elements, a load applied to the elements needs to be even. Thus, flatness of a pressure application surface or parallelism between the pressure application surface and the substrate is required, down to a 1 μm level.

However, when the substrate or the like is heated using the heating means at the time of pressure application using the pressure application means, such heat may affect a jig providing the pressure application means and may cause deformation of the jig. As a result, flatness of the pressure application surface or parallelism between the pressure application surface and the substrate may be reduced to cause unevenness between joining states of the elements joined to the substrate. In this regard, as a measure for preventing heat transfer from the heating means to the pressure application means, placement of a thermally insulating material to the pressure application means or the like is conceivable.

### PRIOR ARTS

### Patent Document

Patent Document 1: JP Patent Application Laid Open No. 2010-232234

### SUMMARY OF INVENTION

### Problem to be solved by Invention

However, placement of the thermally insulating material to the pressure application means may cause deformation of the thermally insulating material and/or the pressure application means because of a difference in coefficient of thermal expansion between the thermally insulating material and the pressure application means (e.g., a plate for applying pressure to the elements). In this regard, the present inventors have found a use of a glass fiber based material with relatively low thermal conductivity as a material of the thermally insulating material to avoid such a fault; however, the possibility of the following faults has been found.

That is, the glass fiber based material has high absorbency and is readily affected by creep. Thus, a thermally insulating material composed of the glass fiber based material is disadvantageous in that deformation due to absorbency and creep readily occurs. When deformation of the thermally insulating material affects the pressure application means (e.g., the plate for applying pressure to the elements), flatness of the pressure application surface or parallelism between the pressure application surface and the substrate may be reduced to cause unevenness between the joining states of the elements joined to the substrate.

The present disclosure is achieved in view of such circumstances. It is an object of the disclosure to provide a substrate processing device that can apply an even load to a workpiece.

### Means for Solving the Problem

To achieve the above object, a substrate processing device of a first aspect of the present disclosure includes
a base part configured to receive a load;
an upper jig plate provided with a heat source;
a pressure application plate attached to the upper jig plate and configured to apply pressure to a workpiece; and
a supporting part interposed between the base part and the upper jig plate and supporting the upper jig plate with respect to the base part,
wherein the supporting part includes a supporting body including a ceramic based material, and an air layer around the supporting body.

The substrate processing device of the present disclosure includes the supporting part, which is interposed between the base part and the upper jig plate and supports the upper jig plate with respect to the base part. The supporting part includes the supporting body composed of the ceramic based material and the air layer around the supporting body. The ceramic based material has low absorbency and is less readily affected by creep. Thus, deformation of the supporting body due to moisture absorption and creep can be prevented. This can prevent reduction of flatness of a pressure application surface or parallelism between the pressure application surface and a substrate, allowing an even load to be applied to the workpiece.

Ceramic based materials in general have a nature of readily having a crack or a breakage when receiving an unbalanced load or a concentrated load. With regard to this point, the substrate processing device of the present disclosure has the air layer around the supporting body so that the supporting body does not support an entire surface of the upper jig plate. This can reduce the contact area between the supporting body and the upper jig plate to prevent a crack or a breakage of the supporting body due to a difference in their coefficients of thermal expansion. Thus, with regard to this point as well, reduction of flatness of the pressure application surface or parallelism between the pressure application surface and the substrate can be prevented, which allows an even load to be applied to the workpiece.

Also, the upper jig plate provided with the heat source is fixed to the base part using the supporting part instead of being fixed directly thereto. Moreover, the supporting body and the air layer play a role as a thermally insulating material. Thus, heat of the upper jig plate (heat source) is prevented from being transferred to the base part. This can maintain evenness of a temperature distribution of the pressure application surface. Additionally, deformation of the base part can be prevented and, in response to that, deformation of the upper jig plate can be prevented. Thus, with regard to this point as well, reduction of flatness of the pressure application surface or parallelism between the pressure application surface and the substrate can be prevented, which allows an even load to be applied to the workpiece.

The supporting body may include ceramics or glass. In a situation where the supporting body is composed of ceramics or, other than that, glass, effects described above can be attained as well.

The supporting body may have a columnar shape. In this situation, the supporting body less readily has a crack or a breakage. The supporting body also enables a distance to be provided between the base part and the upper jig plate, making it difficult for heat of the upper jig plate to be transferred to the base part.

The supporting body may include a plurality of supporting bodies; and the plurality of supporting bodies may be disposed in a matrix. In this situation, the upper jig plate is locally supported by the supporting bodies at their respective locations. Thus, the contact area between each supporting body and the upper jig plate can be reduced to prevent a crack or a breakage of the supporting body due to a difference in their coefficients of thermal expansion. Also, the supporting bodies allow dispersion of a load applied to the supporting part to prevent a crack or a breakage of the supporting bodies due to an unbalanced load.

The supporting body may include a first supporting body disposed at the base part or a central part of the upper jig plate; and the first supporting body may be coupled to the base part and the upper jig plate using a coupling member. In this situation, the first supporting body is fixed to the base part and the upper jig plate using the coupling member. Thus, it is difficult for the first supporting body to be misaligned in a vertical direction and/or a horizontal direction. This can prevent reduction of flatness of the pressure application surface or parallelism between the pressure application surface and the substrate.

A first shaft penetrating the first supporting body along an axial direction of the first supporting body may be fixed to the first supporting body; and one end of the first shaft in an axial direction of the first shaft may be coupled to the base part whereas an other end of the first shaft in the axial direction may be coupled to the upper jig plate. Coupling the first supporting body to the base part and the upper jig plate using the first shaft can increase the strength of coupling among them.

The one end of the first shaft in the axial direction may be provided with a buffer material. In this situation, at the time of thermal expansion of the first supporting body, for example, deformation of the buffer material allows the first supporting body to freely thermally expand without being obstructed by the base part. Thus, stress applied to the first supporting body can be reduced to prevent a crack or a breakage of the first supporting body.

The supporting body includes a second supporting body disposed around the first supporting body; and the second supporting body is coupled to the base part but is in contact with the upper jig plate without being coupled to the upper jig plate. In this situation, at the time of thermal expansion of the second supporting body, the second supporting body can freely thermally expand towards the upper jig plate without being obstructed by the upper jig plate. Thus, stress applied to the second supporting body can be reduced to prevent a crack or a breakage of the second supporting body.

The supporting body may include a first supporting body disposed at the base part or a central part of the upper jig plate; and a holder may be fixed to the first supporting body, the holder being disposed along an outer circumference of the first supporting body so as to surround the first supporting body. In this situation, the holder can prevent misalignment of the first supporting body in the horizontal direction or rotation of the first supporting body or the upper jig plate.

To achieve the above object, a substrate processing device of a second aspect of the present disclosure includes
a base part configured to receive a load;
an upper jig plate provided with a heat source;
a pressure application plate attached to the upper jig plate and configured to apply pressure to a workpiece;
a supporting part interposed between the base part and the upper jig plate and supporting the upper jig plate with respect to the base part; and
a holding part displaceably holding the upper jig plate with respect to the base part.

The substrate processing device of the present disclosure includes the supporting part, which is interposed between the base part and the upper jig plate and supports the upper jig plate with respect to the base part. Thus, the upper jig plate provided with the heat source is fixed to the base part using the supporting part instead of being fixed directly thereto. This can prevent heat of the upper jig plate (heat source) from being transferred to the base part to maintain evenness of a temperature distribution of a pressure application surface. Additionally, deformation of the base part can be prevented and, in response to that, deformation of the upper jig plate can be prevented. Thus, reduction of flatness of the pressure application surface or parallelism between the pressure application surface and a substrate can be prevented, which allows an even load to be applied to the workpiece.

Also, the substrate processing device of the present disclosure includes the holding part displaceably holding the upper jig plate with respect to the base part. Thus, the holding part can displace the upper jig plate with respect to the base part according to thermal expansion of the upper jig plate or the like. The upper jig plate can thus freely thermally expand without being obstructed by the holding part. Consequently, deformation of the upper jig plate in response to its uneven thermal expansion can be prevented. Thus, with regard to this point as well, reduction of flatness of the pressure application surface or parallelism between the pressure application surface and the substrate can be prevented, which allows an even load to be applied to the workpiece. Also, free thermal expansion of the upper jig plate can reduce stress applied to the supporting part to prevent a crack or a breakage of the supporting part.

The holding part may include an elastic body with elastic force lifting the upper jig plate. In this situation, using the elastic force of the elastic body, the holding part can freely displace the upper jig plate with respect to the base part according to thermal expansion of the upper jig plate or the like.

The holding part may include a main body holding the upper jig plate, a second shaft fixed at one end to the base part and slidably holding the main body, and an elastic body fixed to the second shaft and configured to bias the main body towards the base part using elastic force. In this situation, the main body under a state of holding the upper jig plate can be fixed to the base part while the main body under such a state is biased towards the base part using biasing force of the elastic body. Also, the main body can slide along the second shaft according to thermal expansion of the upper jig plate or the like. This enables the main body to displaceably hold the upper jig plate with respect to the base part.

The elastic force of the elastic body may be balanced with weight of an object held by the holding part. In this situation, obstruction of thermal expansion of the upper jig plate or the like by the elastic force of the elastic body can be prevented.

The second shaft may include a plurality of second shafts; the elastic body may include a plurality of elastic bodies fixed to the plurality of second shafts; and the plurality of elastic bodies may be configured to bias the main body towards the base part using the elastic force. In this situation, using the elastic force of the elastic bodies, the main body can have increased force of lifting the upper jig plate. Thus, inclination of the upper jig plate can be prevented to prevent reduction of parallelism between the pressure application surface and the substrate.

The elastic body may include a coil-shaped spring; and the second shaft may be inserted into the elastic body. In this situation, the elastic body can bias the main body towards the base part using resilience of the spring.

The holding part may include a plurality of holding parts; and the plurality of holding parts may hold a peripheral part of the upper jig plate. The holding parts holding the peripheral part of the upper jig plate can prevent obstruction, by the holding parts, of displacement of the upper jig plate with respect to the base part.

A thermally insulating material may be provided between the holding part and the upper jig plate. The thermally insulating material may be interposed between the holding part and the upper jig plate, the holding part and the upper jig plate not being in contact with each other. In this situation, heat of the upper jig plate can be prevented from being transferred to the holding part to maintain evenness of the temperature distribution of the pressure application surface. Additionally, deformation of the holding part can be prevented and, in response to that, deformation of the upper jig plate can be prevented. Thus, reduction of flatness of the pressure application surface or parallelism between the pressure application surface and the substrate can be prevented, which allows an even load to be applied to the workpiece.

### BRIEF DESCRIPTION OF THE DRAWINGS

FIG. 1A is a perspective view of a substrate processing device of a first embodiment.

FIG. 1B is a side elevational view of the substrate processing device shown in FIG. 1A.

FIG. 2 is a plan view of a substrate to which pressure is to be applied by the substrate processing device.

FIG. 3A is a perspective view of a substrate pressure application unit (an upper jig unit) of the substrate processing device shown in FIG. 1A.

FIG. 3B is a perspective view of the upper jig unit, shown in FIG. 3A, having a cover removed.

FIG. 4 is a plan view of a supporting part and an upper jig plate shown in FIG. 3B.

FIG. 5 is a sectional view of a base plate, a placement part, the supporting part, and the upper jig plate shown in FIG. 3B along an XZ plane.

FIG. 6 is a plan view of the supporting part and the upper jig plate shown in FIG. 3B.

FIG. 7 is a side elevational view of the upper jig unit shown in FIG. 3B viewed from the X-axis direction.

FIG. 8 is a side elevational view of the upper jig unit shown in FIG. 3B viewed from the Y-axis direction.

FIG. 9 is an enlarged sectional view of a holding part shown in FIG. 8 along an XZ plane.

FIG. 10A is a view showing a distribution of a load applied to pressure-sensitive paper at the time of application of pressure by the upper jig unit without the supporting part to the pressure-sensitive paper in an unheated atmosphere.

FIG. 10B is a view showing a distribution of a load applied to pressure-sensitive paper at the time of application of pressure by the upper jig unit provided with the supporting part to the pressure-sensitive paper in an unheated atmosphere.

FIG. 11A is a view showing a distribution of a load applied to pressure-sensitive paper at the time of application of pressure by the upper jig unit without the supporting part to the pressure-sensitive paper in a heated atmosphere.

FIG. 11B is a view showing a distribution of a load applied to pressure-sensitive paper at the time of application of pressure by the upper jig unit provided with the supporting part to the pressure-sensitive paper in a heated atmosphere.

FIG. 12A is a plan view of a supporting part of a substrate processing device of a second embodiment.

FIG. 12B is a plan view of a supporting part of a substrate processing device of a third embodiment.

FIG. 12C is a plan view of a supporting part of a substrate processing device of a fourth embodiment.

FIG. 12D is a plan view of a supporting part of a substrate processing device of a fifth embodiment.

FIG. 12E is a plan view of a supporting part of a substrate processing device of a sixth embodiment.

FIG. 12F is a plan view of a supporting part of a substrate processing device of a seventh embodiment.

### DETAILED DESCRIPTION OF INVENTION

Embodiments of the present disclosure are described with reference to the drawings. Although the embodiments are described with reference to the drawings as necessary, the illustrated contents are only schematically and exemplarily provided for understanding of the present disclosure; and the appearance, dimensional ratios, and the like may be different from actual ones. The present disclosure is more specifically described below based on the embodiments but is not limited to these embodiments.

### First Embodiment

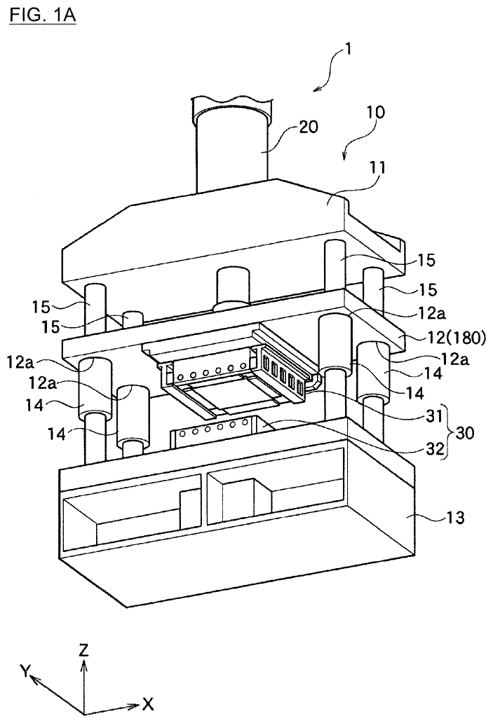

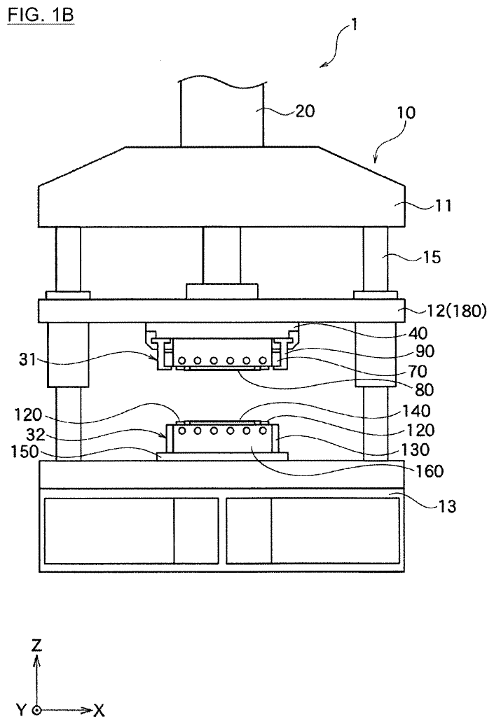

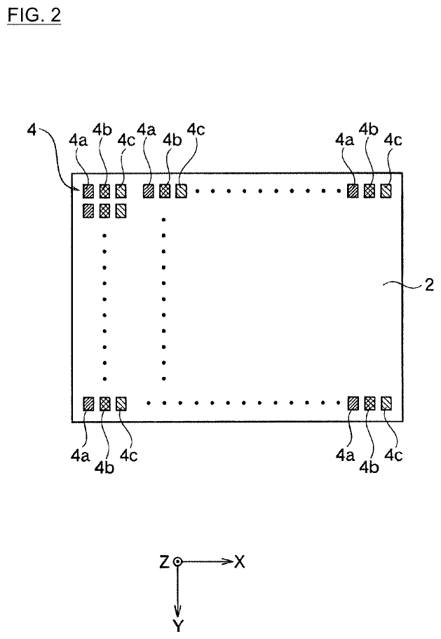

A substrate processing device 1 of a first embodiment shown in FIG. 1A is a device for forming an element array 4 (FIG. 2) composed of a plurality of elements 4a, 4b, and 4c on a substrate 2. The substrate processing device 1 includes a substrate pressure application unit 30. The substrate processing device 1 may further include a stand 10 and a load-generating part 20. Using the substrate pressure application unit 30, the substrate processing device 1 functions as a pressure application device for applying pressure to the elements 4a, 4b, and 4c (FIG. 2) temporarily fixed to the substrate 2 for final fixation.

The substrate 2 shown in FIG. 2 may be made from any material. Examples of such materials include glass epoxy materials. The substrate 2 may be composed of glass, such as SiO₂ or Al₂O₃. Alternatively, the substrate 2 may be composed of elastomers (e.g., polyimide, polyamide, polypropylene, polyetheretherketone, urethane, silicone, polyethylene terephthalate, or polyethylene naphthalate), glass wool, or the like. In this situation, the substrate 2 can function as a flexible substrate.

A surface of the substrate 2 is provided with, for example, a conductive joining material not shown in the drawings. This conductive joining material may have a nature of hardening by heating. The conductive joining material electrically and mechanically connects the substrate 2 and the elements 4a, 4b, and 4c using anisotropic conductive particle connection, bump pressure welding connection, or the like. Examples of such conductive joining materials include ACF, ACP, NCF, and NCP. The conductive joining material has a thickness of preferably 1.0 to 10000 μm.

The substrate 2 is provided with wiring in a predetermined pattern. To the wiring, electrodes of the elements 4a, 4b, and 4c can be connected using the conductive joining material.

The elements 4a, 4b, and 4c are disposed on the substrate 2 in an array shape. The array shape denotes a state where the elements 4a, 4b, and 4c are disposed according to a determined pattern in multiple rows and multiple columns. Note that distances between rows or columns may be the same or different. Note that, in the present embodiment, “equivalent to” or “the same” is not limited to a situation where something is strictly equivalent to or the same as something else; and a ±10% or less difference therebetween is allowed.

The elements 4a, 4b, and 4c are arranged as, for example, RGB pixels of a display substrate. Alternatively, the elements 4a, 4b, and 4c are arranged as, for example, backlight emitters in a lighting substrate. The element 4a is a red-light emitting element. The element 4b is a green-light emitting element. The element 4c is a blue-light emitting element. However, elements disposed on the substrate 2 are not limited to these elements.

The elements 4a, 4b, and 4c are, for example, micro light-emitting elements (micro LED elements). The elements 4a, 4b, and 4c may have any size (width×depth). The size is, for example, 5 μm×5 μm to 50 μm×50 μm. The elements 4a to 4c may have any thickness (height). The height is, for example, 50 μm or less.

As shown in FIG. 1A, the substrate processing device 1 includes the stand 10, the load-generating part 20, and the substrate pressure application unit 30. In the drawings, the X-axis is an axis extending along a long side of a rectangular shape of the stand 10 in plan view. The Y-axis is an axis extending along a short side of the rectangular shape of the stand 10 in plan view. The Z-axis is an axis perpendicular to the X-axis and the Y-axis. Hereinafter, the positive direction of the Z-axis is referred to as an upward direction, and the negative direction of the Z-axis is referred to as a downward direction. With regard to the X-axis, the Y-axis, and the Z-axis, a direction towards a center of the substrate processing device 1 is referred to as an inward direction, and a direction away from the center of the substrate processing device 1 is referred to as an outward direction.

The stand 10 is composed of, for example, a metal enclosure. The stand 10 includes a stand upper part 11, a movable pressure application part 12, a stand lower part 13, guide bushes 14, and guide shafts 15. The stand lower part 13 constitutes a foundation part of the stand 10. The stand lower part 13 has a hollow part inside but may have any shape. To four corners of the stand lower part 13, lower ends of the four guide shafts 15 are fixed. The guide shafts 15 are disposed upright in the Z-axis direction. The lower ends of the guide shafts 15 are fixed to the stand lower part 13, and upper ends of the guide shafts 15 are fixed to the stand upper part 11. The guide shafts 15 penetrate the movable pressure application part 12. The guide shafts 15 play a role in supporting the stand upper part 11 and play a role in vertically slidably supporting the movable pressure application part 12.

The movable pressure application part 12 is composed of a plate (rigid body) having a rectangular shape and is located between the stand lower part 13 and the stand upper part 11. The movable pressure application part 12 is configured to freely slide vertically along the four guide shafts 15 in response to a load applied by the load-generating part 20.

At four respective corners of the movable pressure application part 12, four through-holes 12a are provided. To the four respective through-holes 12a, the four guide bushes 14 are fixed. Into the respective four guide bushes 14, the four guide shafts 15 are inserted. The guide bushes 14 have a function of enabling the movable pressure application part 12 to slide better (reducing friction with the guide shafts 15) at the time of a vertical movement of the movable pressure application part 12. The guide bushes 14 also have a function of positioning the guide shafts 15 with respect to axes of the through-holes 12a.

The stand upper part 11 constitutes a ceiling part of the stand 10. To four corners of the stand upper part 11, the upper ends of the four guide shafts 15 are fixed. To a central part of the stand upper part 11, the load-generating part 20 is fixed. The load-generating part 20 is composed of a device, such as a pressure application cylinder, a servo press, a motor, or an actuator, and plays a role in applying a load to the movable pressure application part 12. Note that, to prevent complexity of the drawings, illustrations of detailed structures of the movable pressure application part 12 are omitted, and only some of such structures are shown in the drawings.

The load-generating part 20 is configured to apply pressure to a central part of an upper surface of the movable pressure application part 12 using a press head (not shown in the drawings) to apply a load to the movable pressure application part 12. The direction in which the load is applied by the load-generating part 20 is the Z-axis direction. This enables the substrate pressure application unit 30 (an upper jig unit 31), together with the movable pressure application part 12, to move downwards.

As shown in FIG. 1B, the substrate pressure application unit 30 includes the upper jig unit 31 provided at the movable pressure application part 12 and a lower jig unit 32 provided at the stand lower part 13. The lower jig unit 32 includes a lower jig plate 130. The lower jig unit 32 may further include a placement base 140, a stage 150, and a cover 160.

The stage 150 is composed of a plate (rigid body) having a flat plate shape and is provided on an upper surface of the stand lower part 13. The stage 150 may have higher surface accuracy (flatness, smoothness, etc.) than that of the upper surface of the stand lower part 13.

The lower jig plate 130 is composed of a plate (rigid body) having a flat plate shape and is provided on an upper surface of the stage 150. The lower jig plate 130 may be made from any material; and the material is metal, such as SUS, steel, or nickel. The thickness of the lower jig plate 130 in the Z-axis direction is thicker than the thickness of the stage 150 in the Z-axis direction.

The placement base 140 is composed of a plate (rigid body) having a flat plate shape and is provided on an upper surface of the lower jig plate 130. On the placement base 140, the substrate 2 (FIG. 2), which is a workpiece, is to be disposed. Arrangement of the placement base 140 between the lower jig plate 130 and the substrate 2 makes it difficult for deformation (thermal expansion) of the lower jig plate 130 to affect the substrate 2. Thus, when the upper jig unit 31 (a pressure application plate 80 described later) applies pressure to the substrate 2, the pressure application plate 80 and the substrate 2 are readily in parallel, which allows an even load to be applied to the substrate 2 (the elements 4a, 4b, and 4c shown in FIG. 2).

The placement base 140 may have higher surface accuracy (flatness, smoothness, etc.) than that of the lower jig plate 130. An upper surface of the placement base 140 may have, for example, less unevenness and smaller inclination with respect to a horizontal plane than those of the upper surface of the lower jig plate 130. A surface (particularly, the upper surface) of the placement base 140 may have any surface roughness Ra. Ra≤1 μm may be satisfied. In this situation, inclination of the substrate 2 with respect to the horizontal plane can be prevented when the substrate 2 is placed on the placement base 140.

The area of the placement base 140 may be smaller than the area of the lower jig plate 130 and larger than the area of the substrate 2 (FIG. 2). The thickness of the placement base 140 in the Z-axis direction may be smaller than the thickness of the lower jig plate 130 in the Z-axis direction.

The placement base 140 may be composed of a material with a smaller coefficient of thermal expansion than that of a material constituting the lower jig plate 130. The placement base 140 may be composed of, for example, ceramics or glass. Glass constituting the placement base 140 is not limited and may be NEOCERAM (registered trademark), quartz glass, or the like. Ceramics constituting the placement base 140 may be silicon carbide, silicon nitride, aluminum nitride, aluminum oxide, or the like. Other than the above materials, various inorganic solid materials with a smaller coefficient of thermal expansion than that of the lower jig plate 130 can be used.

Being made from such a material, the placement base 140 can prevent its deformation (thermal expansion). Thus, influence of deformation of the placement base 140 on the substrate 2 (FIG. 2) disposed on the placement base 140 can be prevented. Also, surface accuracy (flatness, smoothness, etc.) of ceramics or glass is readily ensured compared to the metal or the like constituting the lower jig plate 130. Thus, being made from the above material, the placement base 140 can have its surface accuracy ensured.

The upper surface of the lower jig plate 130 is provided with a plurality of fixation parts 120 in contact with a peripheral part of the placement base 140. The fixation parts 120 enable the placement base 140 to be positioned at and fixed to (or temporarily fixed to) a predetermined location on the lower jig plate 130. The fixation parts 120 are in contact with at least a part of the peripheral part of the placement base 140. The fixation parts 120 may be provided to correspond to sides of a rectangular shape presented by the placement base 140. Note that the number of the fixation parts 120 is not limited. The number of the fixation parts 120 may be, for example, one to three, or five or more.

The cover 160 is attached to, for example, the lower jig plate 130. The cover 160 is for protecting the lower jig plate 130 or the like from external force or the like. The cover 160 may be attached to the lower jig plate 130 so as to cover a side of the lower jig plate 130 in the Y-axis direction.

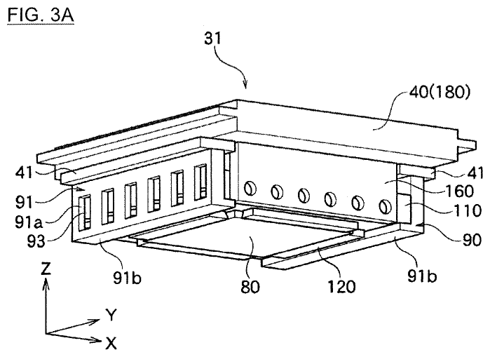

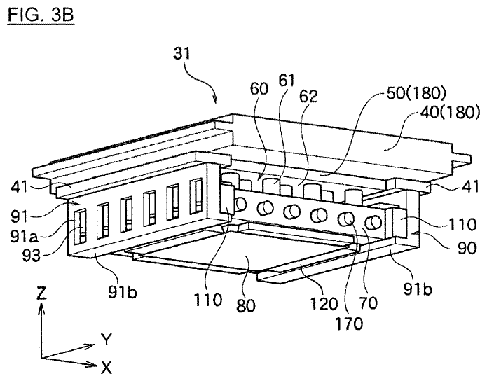

As shown in FIGS. 3A and 3B, the upper jig unit 31 includes a supporting part 60, an upper jig plate 70, the pressure application plate 80, and holding parts 90. It may be that the upper jig unit 31 includes only either the supporting part 60 or the holding parts 90. The upper jig unit 31 may further include a base plate 40, a placement part 50, a thermally insulating material 110, fixation parts 120, and a cover 160.

The base plate 40 is provided at, for example, a lower surface of the movable pressure application part 12 (FIG. 1A). The base plate 40 may be composed of a plate (rigid body) having a flat plate shape. The base plate 40 may be provided with a cooling mechanism (not shown in the drawings).

The placement part 50 is provided at, for example, a lower surface of the base plate 40. The placement part 50 may be composed of a plate (rigid body) having a flat plate shape. The area of the placement part 50 may be smaller than the area of the base plate 40. The placement part 50 has, for example, a length of 100 to 500 mm in the X-axis direction, a length of 100 to 500 mm in the Y-axis direction, and a height (thickness) of 10 to 100 mm.

At the placement part 50, the supporting part 60 (supporting bodies 61 described later) is placed. The placement part 50 plays a role in supporting the supporting bodies 61 so that they are held upright. The placement part 50 may be made from any material. The material may be, for example, a material (ceramic based material) similar to that of the supporting bodies 61 or metal.

The placement part 50 may be integrated with the base plate 40. The base plate 40 may be integrated with the movable pressure application part 12. In the present embodiment, members that are disposed above the supporting part 60 and are configured to receive a load from the load-generating part 20 (FIG. 1A) are collectively referred to as a “base part”. The base part 180 includes the movable pressure application part 12, the base plate 40, and the placement part 50 but may further include other members. Alternatively, any of the movable pressure application part 12, the base plate 40, and the placement part 50 may be omitted from the base part 180.

The upper jig plate 70 is composed of a plate (rigid body) having a flat plate shape and is supported by the supporting part 60. The upper jig plate 70 may be made from metal, such as SUS, steel, or nickel. The upper jig plate 70 is provided separately from the base part 180.

The upper jig plate 70 is provided with a heat source 170. The heat source 170 may be, for example, a cartridge heater, and is built in the upper jig plate 70. Heating the upper jig plate 70 using the heat source 170 allows the upper jig plate 70 (pressure application plate 80) to apply pressure to the substrate 2 (FIG. 2) while heating the substrate 2. Note that the lower jig plate 130 (FIG. 1B) may also be provided with a heat source 170.

The pressure application plate 80 is composed of a plate (rigid body) having a flat plate shape and is provided at a lower surface of the upper jig plate 70. The pressure application plate 80 is for applying pressure to the substrate 2 (FIG. 2) on which the elements 4a, 4b, and 4c are disposed.

The pressure application plate 80 may have higher surface accuracy (flatness, smoothness, etc.) than that of the upper jig plate 70. A lower surface of the pressure application plate 80 may have, for example, less unevenness and smaller inclination with respect to a horizontal plane than the lower surface of the upper jig plate 70. A surface (particularly, the lower surface) of the pressure application plate 80 may have any surface roughness Ra. Ra≤1 μm may be satisfied. In this situation, an even load can be applied to the substrate 2 (the elements 4a, 4b, and 4c shown in FIG. 2) by the pressure application plate 80.

The pressure application plate 80 may have any area. The area may be equivalent to the area of the placement base 140 (FIG. 1B). The pressure application plate 80 may have any thickness in the Z-axis direction. The thickness may be equivalent to the thickness of the placement base 140 in the Z-axis direction. The pressure application plate 80 may be composed of any material. The material may be equivalent to that of the placement base 140. Parallelism A between the pressure application plate 80 and the placement base 140 is not limited. A ≤1 μm may be satisfied.

The lower surface of the upper jig plate 70 is provided with the plurality of (e.g., four) fixation parts 120 in contact with a peripheral part of the pressure application plate 80. The fixation parts 120 enable the pressure application plate 80 to be positioned at and fixed to (or temporarily fixed to) a predetermined location on the upper jig plate 70. The fixation parts 120 are in contact with at least a part of the peripheral part of the pressure application plate 80. The fixation parts 120 may be provided to correspond to sides of a rectangular shape presented by the pressure application plate 80. Note that the number of the fixation parts 120 may be one to three, or five or more.

The cover 160 is attached to, for example, the upper jig plate 70. The cover 160 is for protecting the upper jig plate 70 or the like from external force or the like. The cover 160 may be attached to the upper jig plate 70 so as to cover a side of the upper jig plate 70 in the Y-axis direction.

The supporting part 60 is interposed between the base part 180 (the movable pressure application part 12 (FIG. 1A), the base plate 40, and the placement part 50) and the upper jig plate 70 and supports the upper jig plate 70 with respect to the base part 180. The base part 180 and the upper jig plate 70 are not in contact with each other and are apart, with the supporting part 60 therebetween.

The supporting part 60 includes the supporting bodies 61 and an air layer 62 around the supporting bodies 61. The supporting bodies 61 may have a columnar shape. In this situation, a crack or a breakage of the supporting bodies 61 can be prevented. The supporting bodies 61 enable a distance to be provided between the base part 180 and the upper jig plate 70. This makes it difficult for heat of the upper jig plate 70 (heat source 170) to be transferred to the base part 180.

The supporting bodies 61 have a cylindrical shape but may have a prismatic shape, a conical shape, a pyramidal shape, or the like. Alternatively, the supporting bodies 61 may have a tubular shape. The supporting bodies 61 have the same shape but may have different shapes.

The supporting bodies 61 are fixed to a lower surface of the placement part 50 and support the upper jig plate 70. Upper ends of the supporting bodies 61 are fixed to the placement part 50, whereas lower ends of the supporting bodies 61 are fixed to the upper jig plate 70. Upper end surfaces of the supporting bodies 61 may be in contact with the lower surface of the placement part 50. Lower end surfaces of the supporting bodies 61 may be in contact with an upper surface of the upper jig plate 70.

The supporting bodies 61 may have any diameters. The diameters are, for example, 10 to 20 mm. The diameters (or sectional areas along an XY plane) of the supporting bodies 61 are equivalent but may be different. Among the supporting bodies 61, for example, the supporting body 61 disposed at a central part of the upper jig plate 70 may have a larger diameter (or sectional area) than the diameters (or sectional areas) of other supporting bodies 61.

The supporting bodies 61 may have any length in the Z-axis direction. The length may be, for example, 20 to 50 mm or 20 to 25 mm. The length of the supporting bodies 61 in the Z-axis direction may be equivalent to the thickness of the upper jig plate 70 in the Z-axis direction.

The supporting bodies 61 are composed of a ceramic based material, such as ceramics or glass. Examples of ceramics material constituting the supporting bodies 61 include macerite, silicon nitride, and aluminum oxide. Examples of glass constituting the supporting bodies 61 include quartz, synthetic quartz, sapphire, and NEOCERAM (registered trademark). Other than the above materials, various inorganic solid materials can be used. The supporting bodies 61 may be composed of, for example, metal, such as carbon steel. The material constituting the supporting bodies 61 may have any thermal conductivity. The thermal conductivity is, for example, 1.0 W/mK to 50.0 W/mK. The supporting bodies 61 may be composed of an elastically deformable rigid body. The material constituting the supporting bodies 61 may have any Young's modulus. The Young's modulus is, for example, 70 GPa to 500 GPa.

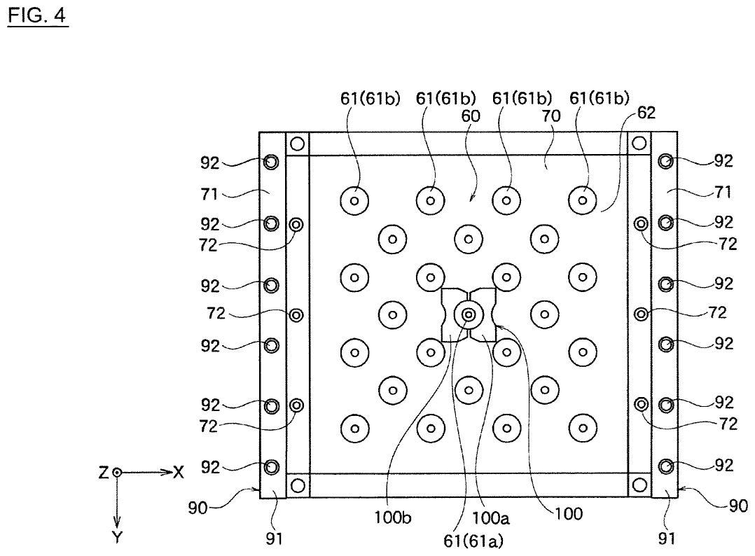

As shown in FIG. 4, the supporting bodies 61 may be disposed on the upper jig plate 70 in a matrix. In this situation, the upper jig plate 70 is locally supported by the supporting bodies 61 at their respective locations. Thus, the contact area between each supporting body 61 and the upper jig plate 70 can be reduced to prevent a crack or a breakage of the supporting body 61 due to a difference in their coefficients of thermal expansion. Also, the supporting bodies 61 allow dispersion of a load applied to the supporting part 60. This can prevent a crack or a breakage of the supporting bodies 61 due to an unbalanced load.

The supporting bodies 61 are disposed apart from each other in the X-axis direction and the Y-axis direction. Thus, between the supporting bodies 61 is the air layer 62. The air layer 62 is provided outwards from the collection of the supporting bodies 61 in the X-axis direction and the Y-axis direction. The air layer 62 is provided along the Z-axis direction, from the lower surface of the placement part 50 (FIG. 3B) to the upper surface of the upper jig plate 70.

The supporting bodies 61 are disposed at regular intervals. The center-to-center distances between the supporting bodies 61 are equivalent but may be different. The center-to-center distances between the supporting bodies 61 are not limited and are, for example, 20 to 50 mm or 20 to 25 mm. The supporting bodies 61 are scattered in the whole area of the upper jig plate 70 but may be unevenly distributed (concentrated) in the central part of the upper jig plate 70. Alternatively, the supporting bodies 61 may be disposed randomly or concentrically on the upper jig plate 70.

The supporting bodies 61 are classified into a first supporting body 61a and second supporting bodies 61b. The first supporting body 61a is disposed at the base part 180 (FIGS. 1A and 3B) and/or the central part of the upper jig plate 70. More specifically, the first supporting body 61a may be disposed directly below a pressure application axis of the load-generating part 20. The second supporting bodies 61b are disposed around (outwards from) the first supporting body 61a.

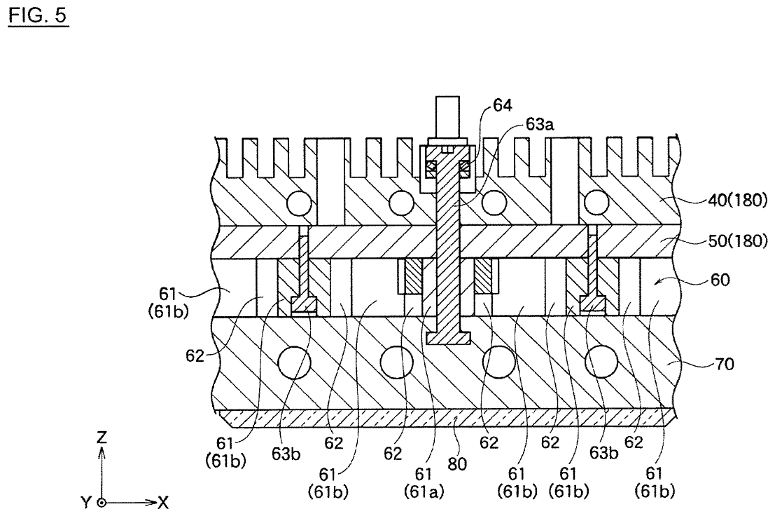

As shown in FIG. 5, the first supporting body 61a may be coupled, using a shaft 63a, to the base part 180 and the upper jig plate 70. The shaft 63a is a fastener, such as a bolt or a rivet. The shaft 63a is fixed to the first supporting body 61a and penetrates the first supporting body 61a along an axial direction (Z-axis direction) of the first supporting body 61a. The shaft 63a also penetrates a through-hole of the placement part 50 along the Z-axis. An upper end of the shaft 63a is coupled to the base plate 40. A lower end of the shaft 63a is coupled to the upper jig plate 70.

In this manner, fixing the first supporting body 61a to the base part 180 and the upper jig plate 70 using the shaft 63a makes it difficult for the first supporting body 61a to be misaligned in the vertical direction and/or the horizontal direction. This can prevent reduction of flatness of a pressure application surface of the pressure application plate 80 or parallelism between the pressure application surface and the substrate 2 (FIG. 2). Also, the strength of coupling among the first supporting body 61a, the base part 180, and the upper jig plate 70 can be increased.

The upper end of the shaft 63a may be provided with a buffer material 64. The buffer material 64 is a biasing member, such as a conical spring washer, a washer, or a leaf spring. In this situation, the upper end of the shaft 63a is fixed to the base plate 40 with relatively weak force with the buffer material 64 therebetween. Thus, at the time of thermal expansion of the first supporting body 61a, for example, deformation of the buffer material 64 allows the first supporting body 61a to freely thermally expand without being obstructed by the base plate 40. Thus, stress applied to the first supporting body 61a can be reduced to prevent a crack or a breakage of the first supporting body 61a.

Note that a coupling member for coupling the first supporting body 61a to the base part 180 and the upper jig plate 70 is not limited to the shaft 63a and may be resin, such as an adhesive. It may also be that the shaft 63a does not penetrate the first supporting body 61a. It may be that, for example, an upper end of the first supporting body 61a is coupled to the base plate 40 using a first shaft whereas a lower end of the first supporting body 61a is coupled to the upper jig plate 70 using a second shaft.

The upper end of the shaft 63a may be coupled to the placement part 50. Alternatively, the upper end of the shaft 63a may penetrate the placement part 50 and the base plate 40 and be coupled to the movable pressure application part 12 (FIG. 1B).

The second supporting bodies 61b may be coupled to the base part 180 using shafts 63b. The shafts 63b are fixed to the second supporting bodies 61b and penetrate the second supporting bodies 61b along an axial direction (Z-axis direction) of the second supporting bodies 61b. Upper ends of the shafts 63b are coupled to the placement part 50. In contrast, it may be that lower ends of the shafts 63b are not coupled to the upper jig plate 70. In this situation, lower ends of the second supporting bodies 61b are only in contact with the upper surface of the upper jig plate 70.

In this situation, at the time of thermal expansion of the second supporting bodies 61b, the second supporting bodies 61b can freely thermally expand towards the upper jig plate 70 without being obstructed by the upper jig plate 70. Thus, stress applied to the second supporting bodies 61b can be reduced to prevent a crack or a breakage of the second supporting bodies 61b.

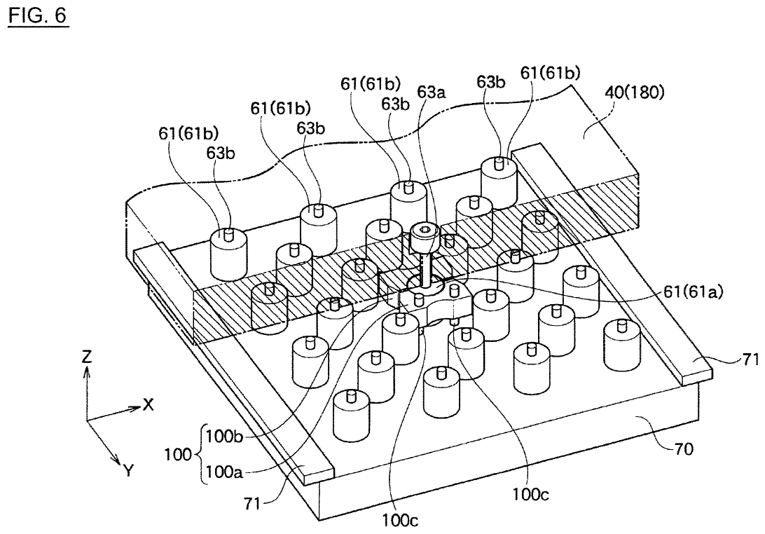

As shown in FIG. 4, a holder 100, which is disposed along an outer circumference of the first supporting body 61a so as to surround the first supporting body 61a, may be fixed to the first supporting body 61a. As shown in FIG. 6, the holder 100 has a tubular shape. The height of the holder 100 in the Z-axis direction may be lower than the height of the first supporting body 61a in the Z-axis direction.

The holder 100 may include a first part 100a and a second part 100b. The first part 100a and the second part 100b are symmetrical in shape but may be asymmetrical. The first supporting body 61a is interposed between the first part 100a and the second part 100b from sides. The holder 100 is thus fixed to the first supporting body 61a.

An upper end of the holder 100 is fixed to the base part 180 (placement part 50) but may also be fixed to the upper jig plate 70. The holder 100 may be fixed to the placement part 50 and/or the upper jig plate 70 using a plurality of (e.g., two) holder fixing members 100c. Fixing the holder 100 to the first supporting body 61a can prevent misalignment of the first supporting body 61a in the horizontal direction or rotation of the first supporting body 61a or the upper jig plate 70.

The holding parts 90 shown in FIG. 3A hold the upper jig plate 70 with respect to the base part 180 (e.g., the base plate 40 and the placement part 50) displaceably in the Z-axis direction. In the present embodiment, the upper jig unit 31 is provided with two holding parts 90.

One holding part 90 is disposed at one side of the upper jig plate 70 in the X-axis direction. The one holding part 90 holds a peripheral part of the upper jig plate 70 at one side thereof in the X-axis direction with the thermally insulating material 110 therebetween; however, the one holding part 90 may directly hold the peripheral part. The other holding part 90 is disposed at the other side of the upper jig plate 70 in the X-axis direction. The other holding part 90 holds the peripheral part of the upper jig plate 70 at the other side thereof in the X-axis direction with the thermally insulating material 110 therebetween; however, the other holding part 90 may directly hold the peripheral part. The holding parts 90 hold the peripheral part of the upper jig plate 70 in the X-axis direction. This can prevent obstruction, by the holding parts 90, of displacement of the upper jig plate 70 with respect to the base part 180.

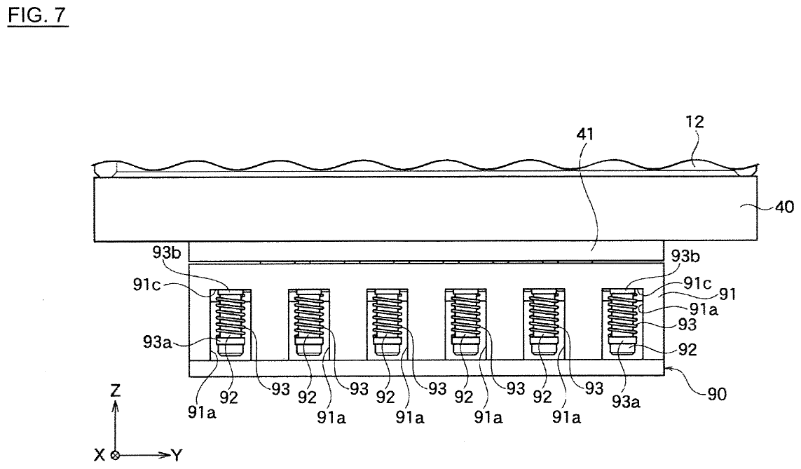

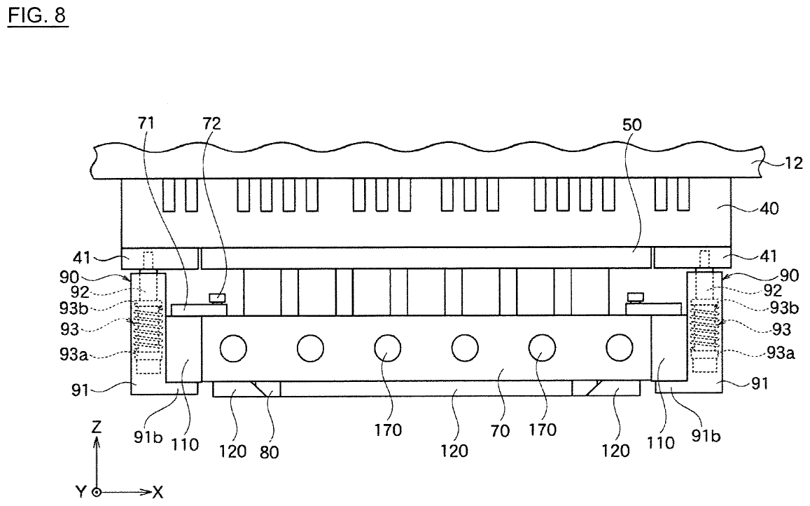

As shown in FIG. 7, each of the holding parts 90 includes a plurality of (e.g., six) elastic bodies 93. The elastic bodies 93 are, for example, coil-shaped compression springs. However, the elastic bodies 93 may be composed of other materials having elasticity (e.g., rubber). As shown in FIG. 8, the holding part 90 lifts the upper jig plate 70 using elastic force of the elastic bodies 93.

As shown in FIGS. 7 and 8, the holding part 90 may further include a main body 91 and a plurality of (e.g., six) shafts 92. The main body 91 has an L shape and holds (lifts) the upper jig plate 70. As shown in FIG. 3A, the main body 91 extends in the Y-axis direction along the peripheral part of the upper jig plate 70 in the X-axis direction. The length of the main body 91 along the Y-axis is not limited. The length may be not less than or not more than the length, along the Y-axis, of the peripheral part of the upper jig plate 70 in the X-axis direction.

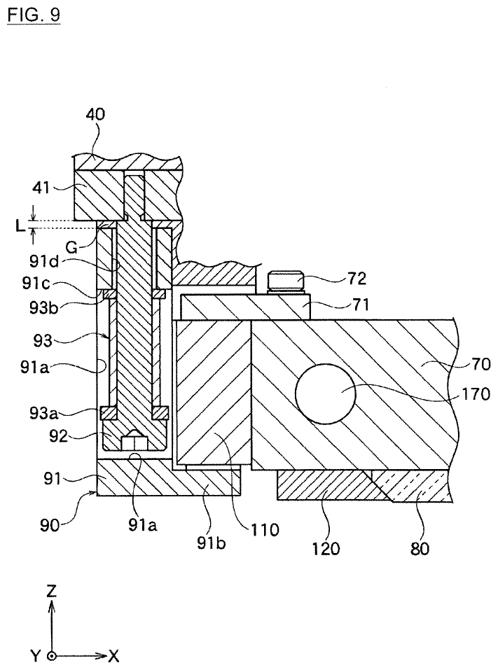

As shown in FIGS. 7 and 8, the main body 91 may include a plurality of (e.g., six) placement holes 91a, a propping part 91b, upper walls 91c, and through-holes 91d (FIG. 9). The placement holes 91a are disposed apart from each other along the Y-axis. The placement holes 91a penetrate the main body 91 along the X-axis; however, one end of each placement hole 91a in the X-axis direction may be closed. The placement holes 91a have a rectangular shape viewed from the X-axis direction; however, the shape is not limited to the rectangular shape.

In the respective placement holes 91a, the elastic bodies 93 and the shafts 92 running through the elastic bodies 93 are disposed. Thus, using the elastic force of the elastic bodies 93, the main body 91 can have increased force of lifting the upper jig plate 70. This can prevent inclination of the upper jig plate 70 to prevent reduction of parallelism between the pressure application surface of the pressure application plate 80 (FIG. 3B) and the substrate 2 (FIG. 2).

The propping part 91b is provided at a lower end of the main body 91 and protrudes along the X-axis. The propping part 91b is integrated with the main body 91 but may be provided separately from the main body 91. The propping part 91b plays a role in supporting the thermally insulating material 110 described later.

The upper walls 91c are parts located at upper sides of inner walls of the placement holes 91a. The upper walls 91c are urged by the elastic bodies 93. As shown in FIG. 9, the through-holes 91d penetrate the main body 91 and extend from an upper end of the main body 91 to the upper walls 91c. The through-holes 91d are connected to the placement holes 91a.

As shown in FIGS. 8 and 9, an upper end of each shaft 92 is fixed to the base part 180 (an attaching part 41, which is a part of the base plate 40), whereas a lower end of the shaft 92 is disposed in the placement hole 91a. The shaft 92 penetrates the main body 91 along the Z-axis and protrudes in the placement hole 91a. The shaft 92 slidably holds the main body 91 along the axial direction.

A lower end of each elastic body 93 is provided with a first-end fixation part 93a. The first-end fixation part 93a is fixed to the lower end of the shaft 92. At the lower end of the shaft 92, a stopper having a larger diameter than other parts is provided for fixation of the first-end fixation part 93a. The first-end fixation part 93a is provided with, for example, a ring-shaped member, which is fixed to the stopper.

An upper end (a second end) of the elastic body 93 is a free end. The upper end of the elastic body 93 is provided with a second-end urging part 93b. In the present embodiment, because the elastic body 93 is a compression spring, the second-end urging part 93b makes the upper wall 91c biased towards the attaching part 41 using resilience of the compression spring. The second-end urging part 93b is provided with, for example, a ring-shaped member, which is in contact with the upper wall 91c.

This enables the main body 91 under a state of holding the upper jig plate 70 to be fixed to the base part 180 while the main body 91 under such a state is biased towards the base part 180 (attaching part 41) using biasing force of the elastic bodies 93. Also, the main body 91 can slide in the Z-axis direction along the shafts 92 according to thermal expansion of the upper jig plate 70 or the like. For example, thermal expansion of the upper jig plate 70 urges the main body 91 using stress applied by the upper jig plate 70 to move the main body 91 downwards. Consequently, between the upper end of the main body 91 and the attaching part 41, a gap G (FIG. 9) having a length L is provided. In contrast, thermal contraction of the upper jig plate 70 releases the main body 91 from the above-mentioned stress to move the main body 91 upwards. Consequently, the gap G disappears. In this manner, the main body 91 can displaceably hold the upper jig plate 70 with respect to the base part 180. Note that the main body 91 may slide in the Z-axis direction along the shafts 92 according to thermal expansion of the supporting bodies 61.

The elastic force of the elastic bodies 93 may be balanced with the weight of the objects (the upper jig plate 70 and the thermally insulating material 110) held by the holding parts 90. This can prevent obstruction of thermal expansion of the upper jig plate 70 or the like by the elastic force of the elastic bodies 93.

Between the propping part 91b of the main body 91 and a propping part 71 of the upper jig plate 70 is the thermally insulating material 110. The propping part 71 is fixed to the upper jig plate 70 using a bolt 72. The thermally insulating material 110 has a rectangular parallelepiped shape and extends along the Y-axis (FIG. 3B). The length of the thermally insulating material 110 along the Y-axis may be not less than the length of the propping part 91b along the Y-axis or may be not more than that length. The thermally insulating material 110 may be composed of any material. The material is, for example, glass fiber. Using glass fiber fixed to resin as the thermally insulating material 110 can prevent a crack or a breakage of the thermally insulating material 110. The thermally insulating material 110 may be composed of a material similar to that of the supporting bodies 61.

The propping part 91b and the propping part 71 are not in contact with each other; and the thermally insulating material 110 is interposed therebetween. In this situation, heat of the upper jig plate 70 can be prevented from being transferred to the main body 91 to maintain evenness of a temperature distribution of the pressure application surface of the pressure application plate 80. Additionally, thermal deformation of the holding parts 90 can be prevented, and, in response to that, deformation of the upper jig plate 70 can be prevented. Thus, reduction of flatness of the pressure application surface of the pressure application plate 80 or parallelism between the pressure application surface and the substrate 2 (FIG. 2) can be prevented, which allows an even load to be applied to the elements 4a, 4b, and 4c (FIG. 2).

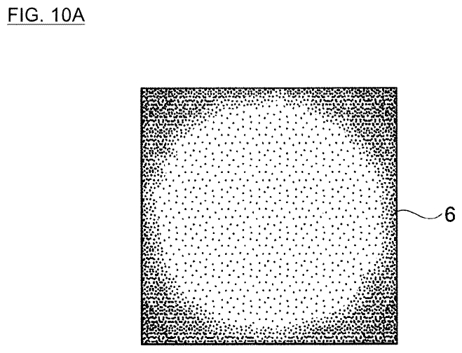

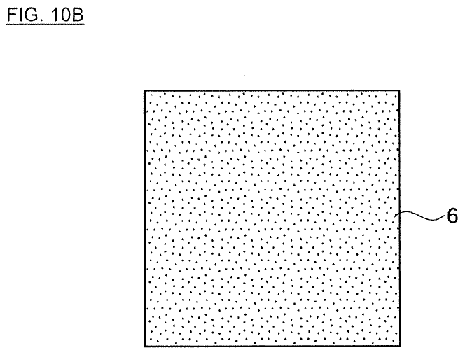

FIG. 10A is a view showing a distribution of a load applied to pressure-sensitive paper 6 disposed at the lower jig unit 32 (placement base 140 (FIG. 1B)) at the time of application of pressure to the pressure-sensitive paper 6 by the upper jig unit 31 without the supporting part 60 shown in FIG. 3B. FIG. 10B is a view showing a distribution of a load applied to pressure-sensitive paper 6 disposed at the lower jig unit 32 (placement base 140 (FIG. 1B)) at the time of application of pressure to the pressure-sensitive paper 6 by the upper jig unit 31 provided with the supporting part 60 shown in FIG. 3B. To the pressure-sensitive paper 6, a load of 6 kN is applied one hundred times in an unheated atmosphere. The distributions of the loads applied to the pressure-sensitive paper 6 in FIGS. 10A and 10B correspond to distributions of loads applied to the substrate 2 (FIG. 2). A relatively large load is applied to a dark-colored part of the drawings, whereas a relatively small load is applied to a light-colored part of the drawings.

In a situation where the upper jig unit 31 (FIG. 3B) is not provided with the supporting part 60 (FIG. 3B), as shown in FIG. 10A, a load applied to the pressure-sensitive paper 6 becomes relatively smaller towards a central part of the pressure-sensitive paper 6 and becomes relatively larger towards a peripheral part of the pressure-sensitive paper 6. In contrast, in a situation where the upper jig unit 31 (FIG. 3B) is provided with the supporting part 60 (FIG. 3B), as shown in FIG. 10B, a load is applied to the pressure-sensitive paper 6 with uniformity at each location. In this manner, in the present embodiment, even if pressure is repeatedly applied to the pressure-sensitive paper 6 by the upper jig unit 31, an even load can be applied to the pressure-sensitive paper 6.

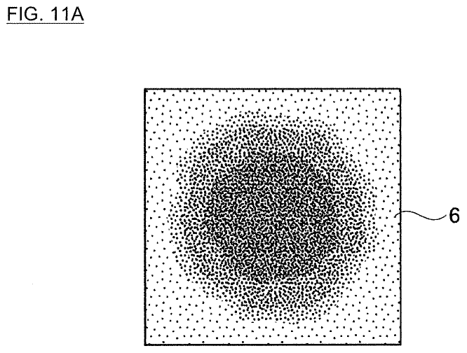

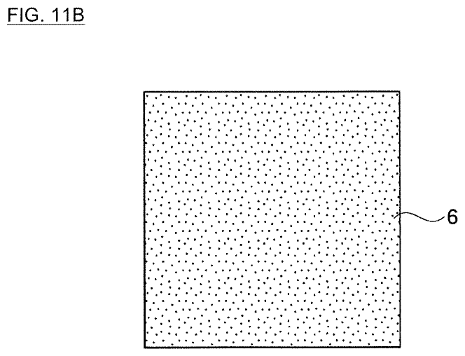

FIG. 11A is a view showing a distribution of a load applied to pressure-sensitive paper 6 disposed at the lower jig unit 32 (placement base 140 (FIG. 1B)) at the time of application of pressure to the pressure-sensitive paper 6 by the upper jig unit 31 without the supporting part 60 shown in FIG. 3B. FIG. 11B is a view showing a distribution of a load applied to pressure-sensitive paper 6 disposed at the lower jig unit 32 (placement base 140 (FIG. 1B)) at the time of application of pressure to the pressure-sensitive paper 6 by the upper jig unit 31 provided with the supporting part 60 shown in FIG. 3B. To the pressure-sensitive paper 6, a load of 6 kN is applied one hundred times in a heated atmosphere at 135° C. The distributions of the loads applied to the pressure-sensitive paper 6 in FIGS. 11A and 11B correspond to distributions of loads applied to the substrate 2 (FIG. 2). A relatively large load is applied to a dark-colored part of the drawings, whereas a relatively small load is applied to a light-colored part of the drawings.

In a situation where the upper jig unit 31 (FIG. 3B) is not provided with the supporting part 60 (FIG. 3B), as shown in FIG. 11A, a load applied to the pressure-sensitive paper 6 becomes relatively larger towards a central part of the pressure-sensitive paper 6 and becomes relatively smaller towards a peripheral part of the pressure-sensitive paper 6. From this, it is found that an uneven load is applied to the pressure-sensitive paper 6. It is assumed that this is because heat of the upper jig plate 70 (heat source 170) shown in FIG. 3B is transferred to the base part 180 and/or the pressure application plate 80 to cause their deformation, reducing flatness of the pressure application surface of the pressure application plate 80 or parallelism between the pressure application surface and the substrate.

In contrast, in a situation where the upper jig unit 31 (FIG. 3B) is provided with the supporting part 60 (FIG. 3B), as shown in FIG. 11B, a load is applied to the pressure-sensitive paper 6 with uniformity at each location. That is, it is found that an even load is applied to the pressure-sensitive paper 6. It is assumed that this is because heat of the upper jig plate 70 (heat source 170) shown in FIG. 3B is less readily transferred to the base part 180 and/or the pressure application plate 80 to less readily cause their deformation and, consequently, reduction of flatness of the pressure application surface of the pressure application plate 80 or parallelism between the pressure application surface and the substrate is prevented.

As described above, as shown in FIG. 3B, in the substrate processing device 1 of the present embodiment, the supporting part 60 includes the supporting bodies 61 composed of the ceramic based material and the air layer 62 around the supporting bodies 61. The ceramic based material has low absorbency and is less readily affected by creep. Thus, deformation of the supporting bodies 61 due to moisture absorption and creep can be prevented. This can prevent reduction of flatness of the pressure application surface of the pressure application plate 80 or parallelism between the pressure application surface and the substrate 2 (FIG. 2), allowing an even load to be applied to the elements 4a, 4b, and 4c (FIG. 2) disposed on the substrate 2.

Ceramic based materials in general have a nature of readily having a crack or a breakage. With regard to this point, the substrate processing device 1 of the present embodiment has the air layer 62 around the supporting bodies 61 so that the supporting bodies 61 do not support an entire surface of the upper jig plate 70. This can reduce the contact area between the supporting bodies 61 and the upper jig plate 70 to prevent a crack or a breakage of the supporting bodies due to a difference in their coefficients of thermal expansion. Thus, with regard to this point as well, reduction of flatness of the pressure application surface of the pressure application plate 80 or parallelism between the pressure application surface and the substrate 2 (FIG. 2) can be prevented, which allows an even load to be applied to the elements 4a, 4b, and 4c (FIG. 2) disposed on the substrate 2.

Also, the upper jig plate 70 provided with the heat source 170 is fixed to the base part 180 using the supporting part 60 instead of being fixed directly thereto. Moreover, the supporting bodies 61 and the air layer 62 play a role as a thermally insulating material. Thus, heat of the upper jig plate 70 (heat source 170) can be prevented from being transferred to the base part 180 to maintain evenness of the temperature distribution of the pressure application surface of the pressure application plate 80. Additionally, thermal deformation of the base part 180 can be prevented and, in response to that, deformation of the upper jig plate 70 can be prevented. Thus, with regard to this point as well, reduction of flatness of the pressure application surface of the pressure application plate 80 or parallelism between the pressure application surface and the substrate 2 (FIG. 2) can be prevented, which allows an even load to be applied to the elements 4a, 4b, and 4c (FIG. 2) disposed on the substrate 2.

Moreover, the substrate processing device 1 includes the holding parts 90, which displaceably hold the upper jig plate 70 with respect to the base part 180. Thus, the holding parts 90 can displace the upper jig plate 70 with respect to the base part 180 according to thermal expansion of the upper jig plate 70. The upper jig plate 70 can thus freely thermally expand without being obstructed by the holding parts 90. Consequently, deformation of the upper jig plate 70 in response to its uneven thermal expansion can be prevented. Thus, with regard to this point as well, reduction of flatness of the pressure application surface of the pressure application plate 80 or parallelism between the pressure application surface and the substrate 2 (FIG. 2) can be prevented, which allows an even load to be applied to the elements 4a, 4b, and 4c (FIG. 2) disposed on the substrate 2. Also, free thermal expansion of the upper jig plate 70 can reduce stress applied to the supporting bodies 61 to prevent a crack or a breakage of the supporting bodies 61.

The holding parts 90 can displace the upper jig plate 70 with respect to the base part 180 according to thermal expansion of the supporting bodies 61. The supporting bodies 61 can thus freely thermally expand without being obstructed by the upper jig plate 70. Consequently, deformation of the supporting bodies 61 in response to their uneven thermal expansion can be prevented, and influence of deformation of the supporting bodies 61 on the upper jig plate 70 can be prevented.

As shown in FIG. 8, the holding parts 90 include the elastic bodies 93, whose elastic force lifts the upper jig plate 70. In this situation, using the elastic force of the elastic bodies 93, the holding parts 90 can freely displace the upper jig plate 70 with respect to the base part 180 according to thermal expansion of the upper jig plate 70 or the like.

### Second Embodiment

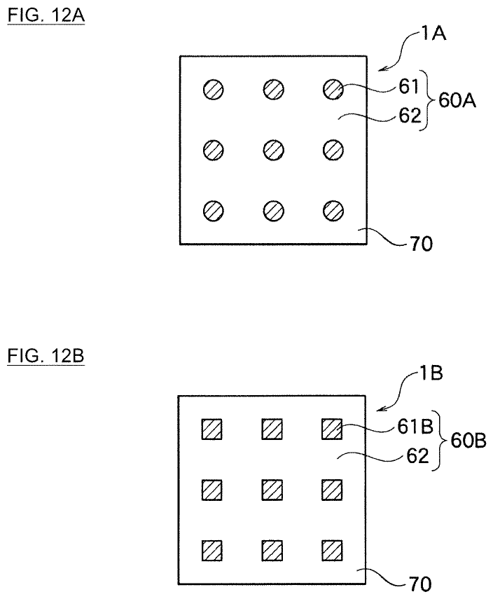

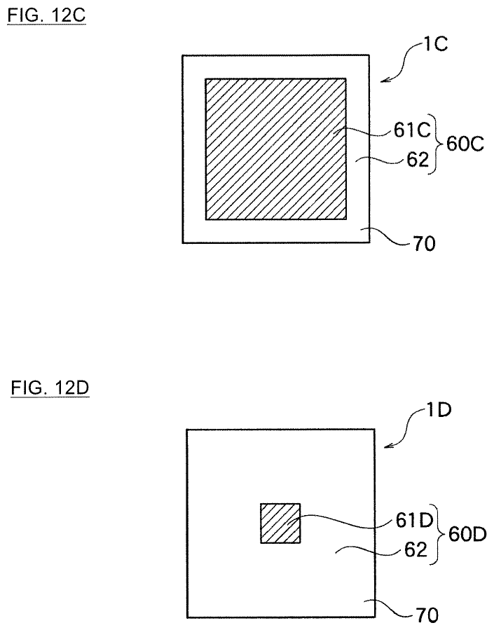

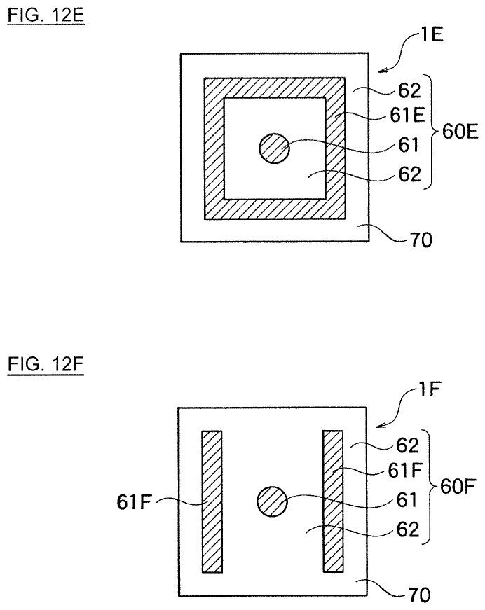

A substrate processing device 1A of a second embodiment shown in FIG. 12A has structures similar to those of the substrate processing device 1 of the first embodiment except for the following. The substrate processing device 1A includes a supporting part 60A. The supporting part 60A is different from the supporting part 60 (FIG. 4) of the first embodiment in that the supporting part 60A includes a plurality of (nine) supporting bodies 61 arranged in three rows and three columns. In a situation where the number of the supporting bodies 61 provided for the supporting part 60 is changed in this manner, effects similar to those of the first embodiment can be attained as well.

### Third Embodiment

A substrate processing device 1B of a third embodiment shown in FIG. 12B has structures similar to those of the substrate processing device 1A of the second embodiment except for the following. The substrate processing device 1B includes a supporting part 60B. The supporting part 60B includes a plurality of (nine) supporting bodies 61B. The supporting bodies 61B are different from the supporting bodies 61 (FIG. 12A) of the second embodiment in that the supporting bodies 61B have a rectangular sectional shape in a direction perpendicular to their axial direction. In a situation where the sectional shape of the supporting bodies 61B is changed in this manner, effects similar to those of the second embodiment can be attained as well. Note that the sectional shape of the supporting bodies 61B may be triangular, other polygonal shape, or other shape.

### Fourth Embodiment

A substrate processing device 1C of a fourth embodiment shown in FIG. 12C has structures similar to those of the substrate processing device 1B of the third embodiment except for the following. The substrate processing device 1C includes a supporting part 60C. The supporting part 60C includes a single supporting body 61C. Around the supporting body 61C, an air layer 62 is provided. The sectional area of a section of the supporting body 61C perpendicular to its axial direction is larger than the sectional area of a section of the supporting bodies 61B (FIG. 12B) perpendicular to their axial direction. The sectional area of a section of the supporting body 61C perpendicular to its axial direction may be ¼ or more of the area of an upper surface of an upper jig plate 70 or may be ½ or more of the area of the upper surface of the upper jig plate 70. In a situation where the sectional area of the supporting body 61C and its number are changed in this manner, effects similar to those of the third embodiment can be attained as well. In particular, in a situation where the number of the supporting body 61C is singular, placement of the supporting part 60C with respect to a placement part 50 (FIG. 3B) is easy.

### Fifth Embodiment

A substrate processing device 1D of a fifth embodiment shown in FIG. 12D has structures similar to those of the substrate processing device 1C of the fourth embodiment except for the following. The substrate processing device 1D includes a supporting part 60D. The supporting part 60D includes a single supporting body 61D. The supporting body 61D is disposed at a central part of an upper jig plate 70. The sectional area of a section of the supporting body 61D perpendicular to its axial direction is smaller than the sectional area of a section of the supporting body 61C (FIG. 12C) perpendicular to its axial direction. The sectional area of a section of the supporting body 61D perpendicular to its axial direction may be ¼ or less of the area of an upper surface of the upper jig plate 70 or may be ⅛ or less of the area of the upper surface of the upper jig plate 70. In a situation where the sectional area of the supporting body 61D is changed in this manner, effects similar to those of the fourth embodiment can be attained as well. Note that the number of the supporting body 61D may be plural.

### Sixth Embodiment

A substrate processing device 1E of a sixth embodiment shown in FIG. 12E has structures similar to those of the substrate processing device 1 of the first embodiment except for the following. The substrate processing device 1E includes a supporting part 60E. The supporting part 60E includes a supporting body 61 disposed at a central part of an upper jig plate 70 and a supporting body 61E surrounding the supporting body 61. Between the supporting body 61 and the supporting body 61E is an air layer 62. The air layer 62 is provided around (outwards from) the supporting body 61E as well. The supporting body 61E has a rectangular ring shape. Sides of the rectangular shape presented by the supporting body 61E are disposed along a peripheral part of the upper jig plate 70. In a situation where the supporting body 61E is in a shape other than a cylindrical shape or a prismatic shape in this manner, effects similar to those of the first embodiment can be attained as well. In particular, in the present embodiment, the supporting body 61E can intensively support the peripheral part of the upper jig plate 70.

Note that the number of the supporting body 61 may be plural. Similarly, the number of the supporting body 61E may be plural. A plurality of supporting bodies 61 may be disposed inwards from the supporting body 61E. Moreover, the supporting bodies 61 may be disposed outwards from the supporting body 61E.

### Seventh Embodiment

A substrate processing device 1F of a seventh embodiment shown in FIG. 12F has structures similar to those of the substrate processing device 1E of the sixth embodiment except for the following. The substrate processing device 1F includes a supporting part 60F. The supporting part 60F includes a supporting body 61 disposed at a central part of an upper jig plate 70 and two supporting bodies 61F disposed at both sides of the supporting body 61. Between the supporting body 61 and the supporting bodies 61F is an air layer 62. The air layer 62 is provided around (outwards from) the supporting bodies 61F as well. The supporting bodies 61F have a rectangular parallelepiped shape and are disposed along a peripheral part of the upper jig plate 70. The supporting bodies 61F have a rectangular shape in a section perpendicular to their axial direction. The number of the supporting bodies 61F may be singular or may be three or more. In a situation where the supporting bodies 61F are in a rectangular parallelepiped shape in this manner, effects similar to those of the sixth embodiment can be attained as well. In particular, in the present embodiment, compared to the sixth embodiment, a crack or a breakage of the supporting bodies 61F can be prevented.

Note that the number of the supporting body 61 may be plural. A plurality of supporting bodies 61 may be disposed between the two supporting bodies 61F. Moreover, the supporting bodies 61 may be disposed outwards from a region interposed between the two supporting bodies 61F.

The present disclosure is not limited to the above-described embodiments and can be variously modified within the scope of the present disclosure.

In each of the above embodiments, either the supporting part 60 or the holding parts 90 shown in FIG. 3B may be omitted from the upper jig unit 31. In a situation where the upper jig unit 31 is provided with the holding parts 90, the supporting bodies 61 may be composed of a material other than the ceramic based material. The supporting bodies 61 may be composed of, for example, a glass fiber based material.

In each of the above embodiments, the supporting part 60 shown in FIG. 3B may be applied to the lower jig unit 32 shown in FIG. 1B.

In each of the above embodiments, the pressure application plate 80 shown in FIG. 3B may be omitted.

In each of the above embodiments, the substrate 2 has a rectangular shape as shown in FIG. 2; however, the substrate 2 may have a circular shape or other polygonal shape.

### REFERENCE NUMERALS

1, 1A to 1F . . . substrate processing device
2 . . . substrate
4 . . . element array
4a, 4b, 4c . . . element
6 . . . pressure-sensitive paper
10 . . . stand
11 . . . stand upper part
12 . . . movable pressure application part
12a . . . through-hole
13 . . . stand lower part
14 . . . guide bush
15 . . . guide shaft
20 . . . load-generating part
30 . . . substrate pressure application unit
31 . . . upper jig unit
32 . . . lower jig unit
40 . . . base plate
41 . . . attaching part
50 . . . placement part
60, 60A to 60F . . . supporting part
61, 61B to 61F . . . supporting body
61a . . . first supporting body
61b . . . second supporting body
62 . . . air layer
63a, 63b . . . shaft (coupling member)
64 . . . buffer material
70 . . . upper jig plate
71 . . . propping part
72 . . . bolt
80 . . . pressure application plate
90 . . . holding part
91 . . . main body
91a . . . placement hole
91b . . . propping part
91c . . . upper wall
91d . . . through-hole
92 . . . shaft
93 . . . elastic body
93a . . . first-end fixation part
93b . . . second-end urging part
100 . . . holder
100a . . . first part
100b . . . second part
100c . . . holder fixing member
110 . . . thermally insulating material
120 . . . fixation part
130 . . . lower jig plate
140 . . . placement base
150 . . . stage
160 . . . cover
170 . . . heat source
180 . . . base part

1. A substrate processing device comprising:
a base part configured to receive a load;
an upper jig plate provided with a heat source;
a pressure application plate attached to the upper jig plate and configured to apply pressure to a workpiece; and
a supporting part interposed between the base part and the upper jig plate and supporting the upper jig plate with respect to the base part,
wherein the supporting part comprises a supporting body comprising a ceramic based material, and an air layer around the supporting body.

2. The substrate processing device according to claim 1, wherein the supporting body comprises ceramics or glass.

3. The substrate processing device according to claim 1, wherein the supporting body has a columnar shape.

4. The substrate processing device according to claim 3, wherein the supporting body has a cylindrical shape, a prismatic shape, a conical shape, or a pyramidal shape.

5. The substrate processing device according to claim 1, wherein
the supporting body comprises a plurality of supporting bodies; and
the plurality of supporting bodies is disposed in a matrix.

6. The substrate processing device according to claim 1, wherein
the supporting body comprises a first supporting body disposed at the base part or a central part of the upper jig plate; and
the first supporting body is coupled to the base part and the upper jig plate using a coupling member.

7. The substrate processing device according to claim 6, wherein
a first shaft penetrating the first supporting body along an axial direction of the first supporting body is fixed to the first supporting body; and
one end of the first shaft in an axial direction of the first shaft is coupled to the base part whereas an other end of the first shaft in the axial direction is coupled to the upper jig plate.

8. The substrate processing device according to claim 7, wherein the one end of the first shaft in the axial direction is provided with a buffer material.

9. The substrate processing device according to claim 6, wherein
the supporting body comprises a second supporting body disposed around the first supporting body; and
the second supporting body is coupled to the base part but is in contact with the upper jig plate without being coupled to the upper jig plate.

10. The substrate processing device according to claim 1, wherein
the supporting body comprises a first supporting body disposed at the base part or a central part of the upper jig plate; and
a holder is fixed to the first supporting body, the holder being disposed along an outer circumference of the first supporting body so as to surround the first supporting body.

11. A substrate processing device comprising:
a base part configured to receive a load;
an upper jig plate provided with a heat source;
a pressure application plate attached to the upper jig plate and configured to apply pressure to a workpiece;
a supporting part interposed between the base part and the upper jig plate and supporting the upper jig plate with respect to the base part; and
a holding part displaceably holding the upper jig plate with respect to the base part.

12. The substrate processing device according to claim 11, wherein the holding part comprises an elastic body with elastic force lifting the upper jig plate.

13. The substrate processing device according to claim 11, wherein the holding part comprises
a main body holding the upper jig plate,
a second shaft fixed at one end to the base part and slidably holding the main body, and
an elastic body fixed to the second shaft and configured to bias the main body towards the base part using elastic force.

14. The substrate processing device according to claim 12, wherein the elastic force of the elastic body is balanced with weight of an object held by the holding part.

15. The substrate processing device according to claim 13, wherein
the second shaft comprises a plurality of second shafts;
the elastic body comprises a plurality of elastic bodies fixed to the plurality of second shafts; and
the plurality of elastic bodies is configured to bias the main body towards the base part using the elastic force.

16. The substrate processing device according to claim 13, wherein
the elastic body comprises a coil-shaped spring; and
the second shaft is inserted into the elastic body.

17. The substrate processing device according to claim 11, wherein
the holding part comprises a plurality of holding parts; and
the plurality of holding parts holds a peripheral part of the upper jig plate.

18. The substrate processing device according to claim 11, wherein a thermally insulating material is provided between the holding part and the upper jig plate.

19. The substrate processing device according to claim 18, wherein the thermally insulating material is interposed between the holding part and the upper jig plate, the holding part and the upper jig plate not being in contact with each other.
